(19) United States
(12) Patent Application Publication
(10) Pub. No.: US 2026/0142551 A1
(43) Pub. Date: May 21, 2026

(54) POWER MODULE AND INVERTER MANUFACTURING METHOD

(71) Applicant: GM Global Technology Operations LLC, Detroit, MI (US)

(72) Inventors: Yilun Luo, Ann Arbor, MI (US); Mohammad N. Anwar, Northville, MI (US); Khorshed Mohammed Alam, Canton, MI (US); Sanjeev M. Naik, Troy, MI (US); Luciano N. Di Perna, Rochester Hills, MI (US); Odavia Schneider, Walled Lake, MI (US)

(21) Appl. No.: 18/953,718

(22) Filed: Nov. 20, 2024

(51) Int. Cl. H02M 1/00; B60L 50/51; H02M 1/32; H02M 7/537

(52) U.S. Cl. CPC H02M 1/0054; B60L 50/51; H02M 1/32; H02M 7/537; B60L 2210/40

(57) ABSTRACT

A method for manufacturing a power inverter may include determining a plurality of electrical characteristics of each of a first power switch die and a second power switch die. The plurality of electrical characteristics includes at least: a conduction loss and a switching loss. The method further may include manufacturing the power inverter using at least the first power switch die and the second power switch die based at least in part on the plurality of electrical characteristics of each of the first power switch die and the second power switch die.

### INTRODUCTION

The present disclosure relates to methods for manufacturing systems and apparatuses for power conversion.

To convert power in vehicle applications, power modules may be utilized. Power modules are self-contained power-electronic devices typically including semiconductor switches configured to be controllable to accomplish power conversion tasks such as, for example, direct current (DC) to alternating current (AC) conversion, AC to DC conversion, DC to DC conversion, and/or the like. In some examples, power modules are configured as a half-bridge with four semiconductor devices, allowing for DC to AC conversion. Multiple power modules may be used in tandem to provide multi-phase AC power to a load such as, for example, a traction motor of a vehicle. Design of power modules is complicated by high current requirements, high voltage requirements, high efficiency requirements, strict size, weight, and resource use constraints, strict electromagnetic interference (EMI) constraints, challenging environmental conditions, and various additional factors. Current power module and inverter manufacturing methods may be unable to utilize components with electrical characteristics outside of normal ranges.

Thus, while current methods for manufacturing power conversion devices achieve their intended purpose, there is a need for a new and improved method for manufacturing power inverters.

### SUMMARY

According to several aspects, a method for manufacturing a power inverter is provided. The method may include determining a plurality of electrical characteristics of each of a first power switch die and a second power switch die. The plurality of electrical characteristics includes at least: a conduction loss and a switching loss. The method further may include manufacturing the power inverter using at least the first power switch die and the second power switch die based at least in part on the plurality of electrical characteristics of each of the first power switch die and the second power switch die.

In another aspect of the present disclosure, determining the plurality of electrical characteristics further may include testing each of the first power switch die and the second power switch die to determine the plurality of electrical characteristics of each of the first power switch die and the second power switch die.

In another aspect of the present disclosure, manufacturing the power inverter further may include assembling at least one power module. The at least one power module includes at least the first power switch die and the second power switch die. Manufacturing the power inverter further may include manufacturing the power inverter including the at least one power module.

In another aspect of the present disclosure, assembling the at least one power module further may include assembling the at least one power module, where a switching loss of the first power switch die is greater than or equal to a predetermined die switching loss threshold and where a total switching loss of the first power switch die and the second power switch die is less than or equal to a predetermined total switching loss threshold.

In another aspect of the present disclosure, assembling at least one power module further may include assembling the at least one power module, where the at least one power module further includes a first gate driver for controlling the first power switch die and a second gate driver for controlling the second power switch die. Assembling at least one power module further may include configuring the first gate driver to control the first power switch die with a first switching slew rate. Assembling at least one power module further may include configuring the second gate driver to control the second power switch die with a second switching slew rate. The second switching slew rate is less than the first switching slew rate.

In another aspect of the present disclosure, configuring the first gate driver and configuring the second gate driver further may include determining the first switching slew rate and the second switching slew rate such that the total switching loss of the first power switch die and the second power switch die is less than or equal to a predetermined total switching loss threshold and such that a first voltage overshoot of the first power switch die and a second voltage overshoot of the second power switch die are less than or equal to a predetermined voltage overshoot threshold.

In another aspect of the present disclosure, assembling at least one power module further may include assembling the at least one power module, where a conduction loss of the first power switch die is greater than or equal to a predetermined die conduction loss threshold. A conduction loss of the second power switch die is less than or equal to the predetermined die conduction loss threshold. A total conduction loss of the first power switch die and the second power switch die is less than or equal to a predetermined total conduction loss threshold.

In another aspect of the present disclosure, assembling at least one power module further may include comparing the conduction loss of the first power switch die to a predetermined die conduction loss threshold. Assembling at least one power module further may include comparing the conduction loss of the second power switch die to the predetermined die conduction loss threshold. Assembling at least one power module further may include procuring one or more additional power switch dies having a conduction loss less than or equal to the predetermined die conduction loss threshold in response to determining that the conduction loss of the first power switch die and the conduction loss of the second power switch die is greater than the predetermined die conduction loss threshold. The one or more additional power switch dies are procured from one of a plurality of suppliers based at least in part on a stock status of each of the plurality of suppliers. Assembling at least one power module further may include assembling the at least one power module using one or more of the additional power switch dies.

In another aspect of the present disclosure, manufacturing the power inverter further may include determining a total power loss of the at least one power module based at least in part on the electrical characteristics of the first power switch die and the electrical characteristics of the second power switch die. Manufacturing the power inverter further may include affixing the at least one power module to a heatsink based at least in part on the total power loss of the at least one power module.

In another aspect of the present disclosure, affixing the at least one power module to the heatsink further may include determining an optimal affixment location of the at least one power module on the heatsink relative to a coolant inlet of the heatsink and a coolant outlet of the heatsink. A distance between the coolant inlet and the optimal affixment location is negatively correlated with the total power loss of the at least one power module.

According to several aspects, a power inverter for a vehicle may include a heatsink including a coolant inlet and a coolant outlet. The power inverter further may include a power module affixed to the heatsink including at least a first power switch die and a second power switch die selected based at least in part on a plurality of electrical characteristics of each of the first power switch die and the second power switch die.

In another aspect of the present disclosure, the plurality of electrical characteristics includes at least a power loss. The power loss is a sum of a switching loss and a conduction loss. A total power loss of the first power switch die of the power module and the second power switch die of the power module is less than or equal to a predetermined total power loss threshold.

In another aspect of the present disclosure, the power module further may include a first gate driver for controlling the first power switch die. The first gate driver is configured to control the first power switch die with a first switching slew rate. The power module further may include a second gate driver for controlling the second power switch die. The second gate driver is configured to control the second power switch die with a second switching slew rate. The second switching slew rate is less than the first switching slew rate.

In another aspect of the present disclosure, the first switching slew rate and the second switching slew rate are determined such that the total power loss of the first power switch die and the second power switch die is less than or equal to a predetermined total power loss threshold and such that a first voltage overshoot of the first power switch die and a second voltage overshoot of the second power switch die are less than or equal to a predetermined voltage overshoot threshold.

In another aspect of the present disclosure, the first switching slew rate and the second switching slew rate are determined such that the first voltage overshoot of the first power switch die and the second voltage overshoot of the second power switch die are less than or equal to the predetermined voltage overshoot threshold in response to determining that the total power loss of the first power switch die and the second power switch die is less than or equal to the predetermined total power loss threshold.

In another aspect of the present disclosure, the power module is affixed to the heatsink at an optimal affixment location relative to the coolant inlet based at least in part on a total power loss of the power module.

In another aspect of the present disclosure, a distance between the coolant inlet and the optimal affixment location is negatively correlated with the total power loss of the power module.

According to several aspects, a method for manufacturing a power inverter for a vehicle is provided. The method may include testing each of a first power switch die and a second power switch die to determine a plurality of electrical characteristics of each of the first power switch die and the second power switch die. The plurality of electrical characteristics includes at least a conduction loss and a switching loss. The method further may include assembling at least one power module based at least in part on the plurality of electrical characteristics of each of the first power switch die and the second power switch die. The at least one power module includes at least the first power switch die and the second power switch die. The method further may include manufacturing the power inverter including the at least one power module based at least in part on the plurality of electrical characteristics of each of the first power switch die and the second power switch die.

In another aspect of the present disclosure, assembling at least one power module further may include assembling the at least one power module, where a switching loss of the first power switch die is greater than or equal to a predetermined die switching loss threshold. The at least one power module further includes a first gate driver for controlling the first power switch die and a second gate driver for controlling the second power switch die. Assembling at least one power module further may include determining a first switching slew rate and a second switching slew rate such that a total switching loss of the first power switch die and the second power switch die is less than or equal to a predetermined total switching loss threshold and such that a first voltage overshoot of the first power switch die and a second voltage overshoot of the second power switch die are less than or equal to a predetermined voltage overshoot threshold. Assembling at least one power module further may include configuring the first gate driver to control the first power switch die with the first switching slew rate. Assembling at least one power module further may include configuring the second gate driver to control the second power switch die with the second switching slew rate. The second switching slew rate is less than the first switching slew rate.

In another aspect of the present disclosure, manufacturing the power inverter further may include determining a total power loss of the at least one power module based at least in part on the electrical characteristics of the first power switch die and the electrical characteristics of the second power switch die. Manufacturing the power inverter further may include determining an optimal affixment location of the at least one power module on a heatsink relative to a coolant inlet of the heatsink and a coolant outlet of the heatsink. A distance between the coolant inlet and the optimal affixment location is negatively correlated with the total power loss of the at least one power module. affixing the at least one power module to a heatsink based at least in part on the optimal affixment location.

Further areas of applicability will become apparent from the description provided herein. It should be understood that the description and specific examples are intended for purposes of illustration only and are not intended to limit the scope of the present disclosure.

### BRIEF DESCRIPTION OF THE DRAWINGS

The drawings described herein are for illustration purposes only and are not intended to limit the scope of the present disclosure in any way.

FIG. 1 is a schematic diagram of a power system for a vehicle, according to an exemplary embodiment;

FIG. 2 is a schematic diagram of a power inverter of the power system, according to an exemplary embodiment;

FIG. 3 is a schematic diagram of a first power module of the power inverter, according to an exemplary embodiment; and

FIG. 4 is a flowchart of a method for manufacturing the power inverter, according to an exemplary embodiment.

### DETAILED DESCRIPTION

The following description is merely exemplary in nature and is not intended to limit the present disclosure, application, or uses.

In aspects of the present disclosure, when manufacturing power electronic devices such as, for example, power inverters for vehicles, it is advantageous to utilize components with known electrical characteristics within acceptable ranges. However, due to manufacturing variation, electrical characteristics within component batches may vary, resulting in components with characteristics outside of normal ranges. The present disclosure provides a new and improved method for manufacturing power inverters for vehicles allowing for the utilization of components with non-ideal electrical characteristics.

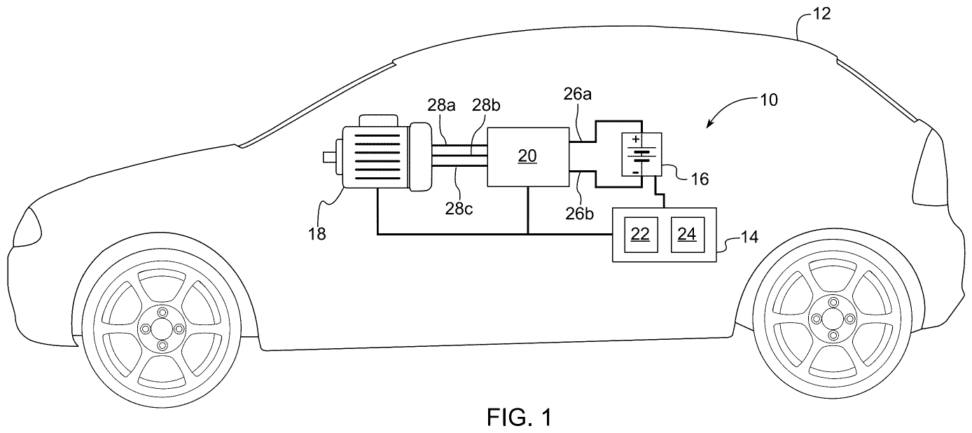

Referring to FIG. 1, a power system for a vehicle is illustrated and generally indicated by reference number 10. The system 10 is shown with an exemplary vehicle 12. While a passenger vehicle is illustrated, it should be appreciated that the vehicle 12 may be any type of vehicle without departing from the scope of the present disclosure. The system 10 generally includes a controller 14, a rechargeable energy storage system (RESS) 16, a traction motor 18, and a power inverter 20.

The controller 14 is used to control the RESS 16, the traction motor 18, and the power inverter 20. The controller 14 includes at least one processor 22 and a non-transitory computer readable storage device or media 24. The processor 22 may be a custom made or commercially available processor, a central processing unit (CPU), a graphics processing unit (GPU), an auxiliary processor among several processors associated with the controller 14, a semiconductor-based microprocessor (in the form of a microchip or chip set), a macroprocessor, a combination thereof, or generally a device for executing instructions.

The computer readable storage device or media 24 may include volatile and nonvolatile storage in read-only memory (ROM), random-access memory (RAM), and keep-alive memory (KAM), for example. KAM is a persistent or non-volatile memory that may be used to store various operating variables while the processor 22 is powered down. The computer-readable storage device or media 24 may be implemented using a number of memory devices such as PROMs (programmable read-only memory), EPROMs (electrically PROM), EEPROMs (electrically erasable PROM), flash memory, or another electric, magnetic, optical, or combination memory devices capable of storing data, some of which represent executable instructions, used by the controller 14 to control various systems of the vehicle 12. The controller 14 may also consist of multiple controllers which are in electrical communication with each other.

The controller 14 is in electrical communication with the RESS 16, the traction motor 18, and the power inverter 20. The controller 14 may also be inter-connected with additional systems and/or controllers of the vehicle 12, allowing the controller 14 to access data such as, for example, speed, acceleration, braking, and steering angle of the vehicle 12. In an exemplary embodiment, the electrical communication is established using, for example, a CAN network, a FLEXRAY network, a local area network (e.g., WiFi, ethernet, and the like), a serial peripheral interface (SPI) network, or the like. It should be understood that various additional wired and wireless techniques and communication protocols for communicating with the controller 14 are within the scope of the present disclosure. It should further be understood that, in the scope of the present disclosure, electrical communication also includes power and/or energy transfer between electrical devices (e.g., using conducting wires and/or wireless power transmission techniques).

The RESS 16 stores and provides electrical energy in the form of direct current (DC) energy for propulsion of the vehicle 12. In an exemplary embodiment, the RESS 16 includes a plurality of battery cells (e.g., lithium-ion battery cells) electrically connected in series and/or parallel to provide an increased voltage and/or current-carrying capacity. In a non-limiting example, the plurality of battery cells are housed in an enclosure configured to protect the plurality of battery cells from mechanical vibration, water intrusion, and dust intrusion. The enclosure is also configured to provide temperature regulation (e.g., using a liquid cooling system, a resistive heating system, and/or the like).

In an exemplary embodiment, the RESS 16 further includes a battery management system (BMS) in electrical communication with the controller 14 configured to monitor battery characteristics such as a state of charge (SOC), state of health (SOH), temperature, and/or the like, and transmit the battery characteristics to the controller 14. In a non-limiting example, the BMS includes a BMS controller in electrical communication with a plurality of BMS sensors disposed within the enclosure of the RESS 16. In another non-limiting example, the BMS further includes one or more electronic switches (e.g., relays, contactors, semiconductor-based switches, and/or the like) which are operable to interrupt current flow through the plurality of battery cells of the RESS 16 in response to commands received from the BMS controller and/or the controller 14. In an exemplary embodiment, the RESS 16 provides a DC voltage across a positive and negative output terminal. The positive and negative output terminals are electrically connected to the power inverter 20 as will be discussed in greater detail below.

The traction motor 18 is used to convert electrical energy from the RESS 16 to mechanical energy (i.e., rotational energy) to propel the vehicle 12. In an exemplary embodiment, the traction motor 18 is a three-phase alternating current (AC) induction motor capable of converting AC energy to mechanical energy. In a non-limiting example, the traction motor 18 includes a stator having a plurality of stator windings and a rotor disposed rotatably within the stator having a plurality of rotor windings. The stator windings are excited by three-phase AC provided by the power inverter 20 to produce a rotating stator magnetic field. The rotating stator magnetic field induces currents in the rotor windings, which in turn produces a rotor magnetic field which interacts with the rotating stator magnetic field causing the rotor to rotate. The amplitude, frequency, and/or relative phase shift of the excitation of each of the three phases of the stator windings controls speed, direction, and/or torque of the traction motor 18. The controller 14 is in electrical communication with the traction motor 18 for monitoring and/or control of the traction motor 18, for example, to measure a temperature, rotational speed, and/or the like of the traction motor 18.

The power inverter 20 is used to convert the direct current (DC) energy provided by the RESS 16 to three-phase alternating current (AC) energy for use by the traction motor 18. In an exemplary embodiment, the power inverter 20 includes a plurality of power semiconductor devices, such as, for example, insulated-gate bipolar transistors (IGBTs), metal-oxide semiconductor field-effect transistors (MOSFETs), and/or the like configured to convert DC to three-phase AC. In a non-limiting example, the power inverter 20 functions by switching the plurality of power semiconductor devices in a pattern to generate an AC sinusoidal output for each of the three phases. The pattern may be adjusted to vary an amplitude, frequency, and/or relative phase shift of each of the three phases in order to control speed, direction, and/or torque of the traction motor 18 based on signals from the controller 14. The power inverter 20 includes a DC positive terminal 26a and a DC negative terminal 26b electrically connected to the RESS 16. The power inverter 20 further includes a first AC terminal 28a, a second AC terminal 28b, and a third AC terminal 28c electrically connected to the traction motor 18. The power inverter 20 is in electrical communication with the controller 14, such that the controller 14 may enable, disable, and otherwise adjust the operation of the power inverter 20. It should be understood that various types of inverters, including, for example, multi-level inverters, are within the scope of the present disclosure.

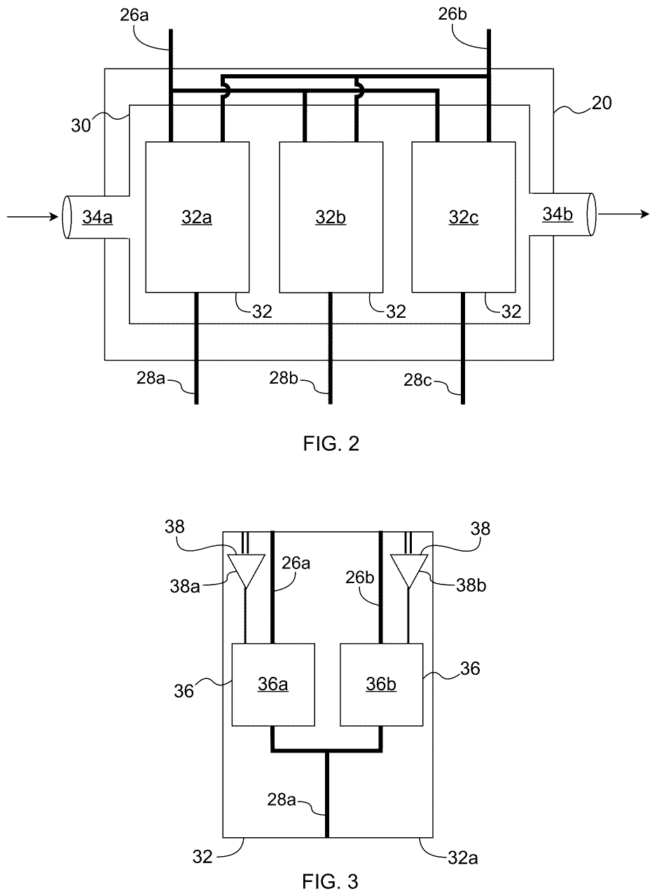

Referring to FIG. 2, a schematic diagram of the power inverter 20 is shown. In an exemplary embodiment, the power inverter 20 includes a heatsink 30 and a plurality of power modules 32.

The heatsink 30 is used to transfer heat away from the plurality of power modules 32 during operation of the power inverter 20. In an exemplary embodiment, the heatsink 30 includes a cooling plate with one or more internal liquid-tight channels for transferring coolant through the heatsink 30. The heatsink 30 further includes a coolant inlet 34a where coolant enters the heatsink 30 and a coolant outlet 34b where coolant exits the heatsink 30. As the coolant flows through the heatsink 30 and absorbs heat from each of plurality of power modules 32, a temperature of the coolant increases. Therefore, in general, the temperature of the coolant entering at the coolant inlet 34a is lower than the temperature of the coolant exiting at the coolant outlet 34b, and a corresponding temperature gradient exists within the heatsink 30 between the coolant inlet 34a and the coolant outlet 34b. In a non-limiting example, after exiting the heatsink 30 through the coolant outlet 34b, the coolant flows through a radiator to release heat absorbed from the plurality of power modules 32.

The plurality of power modules 32 are self-contained modules for converting DC power to AC power. In a non-limiting example, shown in FIG. 2, the power inverter 20 includes a first power module 32a, a second power module 32b, and a third power module 32c. It should be understood that the power inverter 20 may include any number of power modules without departing from the scope of the present disclosure. In an exemplary embodiment, the plurality of power modules 32 are affixed to the heatsink 30 using, for example, a thermal compound, a thermal adhesive, and/or the like.

Referring to FIG. 3, a schematic diagram of the first power module 32a is shown. It should be understood that the following disclosure is also applicable to any number of additional power modules of the power inverter 20, including, for example, the second power module 32b and the third power module 32c. In an exemplary embodiment, the first power module 32a includes a first power switch die 36a and a second power switch die 36b selected from a plurality of power switch dies 36. The first power module 32a further includes a plurality of gate drivers 38 for controlling each of the plurality of power switch dies 36. In a non-limiting example, the plurality of gate drivers 38 includes a first gate driver 38a and a second gate driver 38b. It should be understood that each of the plurality of power modules 32 may include any number of power switch dies and gate drivers.

Each of the plurality of power switch dies 36 includes one or more semiconductor devices such as, for example, transistors, thyristors, triacs, GTOs (gate turn-off thyristors), IGBTs (insulated gate bipolar transistors), MOSFETs (metal-oxide-semiconductor field-effect transistors), SCRs (silicon-controlled rectifiers), and/or the like. The first power switch die 36a is connected to the DC positive terminal 26a and thus is referred to as a “high-side” die. The second power switch die 36b is connected to the DC negative terminal 26b and thus is referred to as a “low-side” die.

In an exemplary embodiment, each of the plurality of power switch dies 36 is characterized by a plurality of electrical characteristics. In a non-limiting example, the plurality of electrical characteristics includes at least: a conduction loss and a switching loss. The conduction loss is caused at least in part by an on-resistance of the power switch die. The switching loss is caused at least in part by a switching energy of the power switch die. In a non-limiting example, the plurality of power switch dies 36 are provided in bulk for the manufacturing process of the plurality of power modules 32. Therefore, the electrical characteristics of the plurality of power switch dies 36 may vary.

To ensure proper operation of the plurality of power modules 32 of the power inverter 20, predetermined thresholds are defined. In an exemplary embodiment, a predetermined die conduction loss threshold is defined as a maximum allowable conduction loss for any individual power switch die. A predetermined total conduction loss threshold is defined as a maximum allowable total conduction loss across all power switch dies in a power module.

A predetermined die switching loss threshold is defined as a maximum allowable switching loss for any individual power switch die. A predetermined total switching loss threshold is defined as a maximum allowable total switching loss across all power switch dies in a power module. The present disclosure provides a new and improved method for manufacturing the power inverter 20 which allows for use of power switch dies which exceed one or more of the thresholds discussed above, increasing manufacturing efficiency.

Each of the plurality of gate drivers 38 controls the switching action of one of the plurality of power switch dies 36. For example, the first gate driver 38a controls the first power switch die 36a and the second gate driver 38b controls the second power switch die 36b. In an exemplary embodiment, each of the plurality of gate drivers 38 includes digital and/or analog circuitry operable to receive control signals from an inverter controller (not shown) or the controller 14 and provide corresponding voltage and/or current pulses to the one of the power switch dies 36 to switch the power switch die on or off. In a non-limiting example, one or more of the plurality of gate drivers 38 is a voltage source gate driver (VSGD), a variable voltage source gate driver (VVSGD), a current source gate driver (CSGD), or a variable current source gate driver (VCSGD) operable to vary switching characteristics such as, for example, slew rate, as will be discussed in greater detail below.

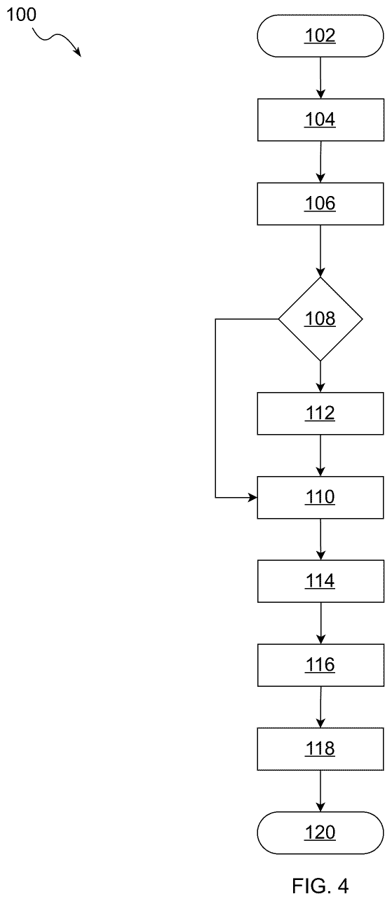

Referring to FIG. 4, a flowchart of a method 100 for manufacturing a power inverter is shown. The method 100 begins at block 102 and proceeds to block 104. At block 104, the plurality of electrical characteristics of each of the plurality of power switch dies 36 are determined. In an exemplary embodiment, the plurality of electrical characteristics includes at least: the conduction loss and the switching loss. In a non-limiting example, the plurality of electrical characteristics are determined by electrical testing of each of the plurality of power switch dies 36 (e.g., measurement of voltage and current during switching and on-state current flow). In another non-limiting example, the plurality of electrical characteristics of each of the plurality of power switch dies 36 are provided by the manufacturer of each of the plurality of power switch dies 36. In an exemplary embodiment, the method 100 may holistically consider electrical characteristics of dies available and/or in stock from multiple suppliers to optimize procurement of the plurality of power switch dies 36. After block 104, the method 100 proceeds to block 106.

At block 106, the first power switch die 36a and the second power switch die 36b are selected from the plurality of power switch dies 36 such that the total conduction loss (i.e., a sum of the conduction loss of the first power switch die 36a and the second power switch die 36b) is less than or equal to the predetermined total conduction loss threshold. In a non-limiting example, the conduction loss of the first power switch die 36a is greater than or equal to a predetermined die conduction loss threshold. Therefore, the second power switch die 36b is selected from the plurality of power switch dies 36 to be a power switch die having a conduction loss less than or equal to the predetermined die conduction loss threshold such as to compensate for the increased conduction loss of the first power switch die 36a. Therefore, even though the conduction loss of the first power switch die 36a exceeds to the predetermined die conduction loss threshold, the first power switch die 36a is still utilized in manufacturing.

In another exemplary embodiment, the first power switch die 36a and the second power switch die 36b are selected from the plurality of power switch dies 36 such that the total switching loss (i.e., a sum of the switching loss of the first power switch die 36a and the second power switch die 36b) is less than or equal to the predetermined total switching loss threshold. In a non-limiting example, the switching loss of the first power switch die 36a is greater than or equal to a predetermined die switching loss threshold. Therefore, the second power switch die 36b is selected from the plurality of power switch dies 36 to be a power switch die having a switching loss less than or equal to the predetermined die switching loss threshold such as to compensate for the increased switching loss of the first power switch die 36a. Therefore, even though the switching loss of the first power switch die 36a exceeds to the predetermined die switching loss threshold, the first power switch die 36a is still utilized in manufacturing.

In another exemplary embodiment, the first power switch die 36a and the second power switch die 36b are selected from the plurality of power switch dies 36 such that the total power loss (i.e., a sum of the conduction and switching loss of the first power switch die 36a and the second power switch die 36b) is less than or equal to a predetermined total power loss threshold. In a non-limiting example, the total loss of the first power switch die 36a is greater than or equal to a predetermined die total power loss threshold. Therefore, the second power switch die 36b is selected from the plurality of power switch dies 36 to be a power switch die having a total power loss less than or equal to the predetermined die total power loss threshold such as to compensate for the increased total power loss of the first power switch die 36a.

In an exemplary embodiment, the method 100 holistically considers the electrical characteristics of dies available and/or in stock from multiple suppliers to optimize procurement of the plurality of power switch dies 36. In a non-limiting example, if one or more of the plurality of power switch dies 36 has a high conduction loss, suppliers may be selected to supply power switch dies with low conduction loss to be used to compensate for the high conduction loss dies. In a non-limiting example, if one or more of the plurality of power switch dies 36 has a low conduction loss, suppliers may be selected to supply power switch dies with high conduction loss to be used to compensate for the high conduction loss dies, thereby utilizing dies which may otherwise be rejected.

In a non-limiting example, the conduction loss of the first power switch die 36a and the second power switch die 36b is compared to the predetermined die conduction loss threshold. If the conduction loss of the first power switch die 36a and the second power switch die 36b are greater than the predetermined die conduction loss threshold, one or more additional power switch dies having a conduction loss less than or equal to the predetermined die conduction loss threshold are procured. The one or more additional power switch dies are procured from one of a plurality of suppliers based at least in part on a stock status (i.e., conduction loss characteristics of power switch dies in stock) of each of the plurality of suppliers. After block 106, the method 100 proceeds to block 108.

At block 108, the total switching loss of the first power switch die 36a and the second power switch die 36b (i.e., a sum of the switching loss of the first power switch die 36a and the second power switch die 36b) is determined. In an exemplary embodiment, the total switching loss is determined based at least in part on the plurality of electrical characteristics determined at block 104. In a non-limiting example, the switching loss of the first power switch die 36a is greater than or equal to the predetermined die switching loss threshold and the switching loss of the second power switch die 36b is greater than or equal to the predetermined die switching loss threshold, resulting in the total switching loss being greater than or equal to the predetermined total switching loss threshold.

If the total switching loss of the first power switch die 36a and the second power switch die 36b is less than or equal to the predetermined total switching loss threshold, the method 100 proceeds to block 110, as will be discussed in greater detail below. If the total switching loss of the first power switch die 36a and the second power switch die 36b is greater than the predetermined total switching loss threshold, the method 100 proceeds to block 112. In another exemplary embodiment, if the total power loss of the first power switch die 36a and the second power switch die 36b is greater than the predetermined total power loss threshold, the method 100 also proceeds to block 112.

At block 112, a first switching slew rate and a second switching slew rate is determined. The first switching slew rate is a switching slew rate for the first power switch die 36a. The second switching slew rate is a switching slew rate for the second power switch die 36b. In an exemplary embodiment, the switching loss of the power switch die is negatively correlated with the switching slew rate (i.e., increasing the switching slew rate results in decreased switching loss). However, a voltage overshoot (i.e., voltage spikes caused by stray inductances in the power module) of the power switch die is positively correlated with the switching slew rate (i.e., increasing the switching slew rate results in increased voltage overshoot). In a non-limiting example, the first switching slew rate and the second switching slew rate are both determined such that the total switching loss is less than or equal to the predetermined total switching loss threshold and such that a first voltage overshoot of the first power switch die 36a and a second voltage overshoot of the second power switch die 36b are both less than or equal to a predetermined voltage overshoot threshold.

In another non-limiting example, the first switching slew rate and the second switching slew rate are both determined such that the total power loss is less than or equal to the predetermined total power loss threshold and such that a first voltage overshoot of the first power switch die 36a and a second voltage overshoot of the second power switch die 36b are both less than or equal to the predetermined voltage overshoot threshold. For example, if the total conduction loss is greater than the predetermined total conduction loss threshold, the first switching slew rate and/or the second switching slew rate may be increased to reduce the total switching loss, thus ensuring that the total power loss is less than or equal to the predetermined total power loss threshold.

In an exemplary embodiment, the first switching slew rate and the second switching slew rate are calculated using a mathematical and/or electrical circuit model of the first power switch die 36a and the second power switch die 36b based at least in part on the plurality of electrical characteristics of the first power switch die 36a and the second power switch die 36b determined at block 104.

In a non-limiting example where the switching loss of the first power switch die 36a is greater than or equal to the predetermined die switching loss threshold and the switching loss of the second power switch die 36b is less than the predetermined die switching loss threshold, the first switching slew rate is determined to be greater than the second switching slew rate to compensate for the increased switching loss of the first power switch die 36a such that the total switching loss remains less than or equal to the predetermined total switching loss threshold. Furthermore, the second switching slew rate may be decreased to reduce drain-source voltage overshoot across the second power switch die 36b. After block 112, the method 100 proceeds to block 110.

At block 110, the first power module 32a is assembled using at least the first power switch die 36a, the second power switch die 36b, the first gate driver 38a, and the second gate driver 38b. As discussed above, it should be understood that each of the plurality of power modules 32 may include any number of power switch dies and gate drivers. In a non-limiting example, the first power switch die 36a, the second power switch die 36b, the first gate driver 38a, and the second gate driver 38b are affixed to a dielectric substrate (e.g., a direct bonded copper substrate). Electrical connections between the components are established using a plurality of conductors (e.g., busbars, bonding wires, bonding clips, bonding ribbons, and/or the like). Control terminals for connecting the gate drivers to the inverter controller (not shown) and/or the controller 14 are realized as pins extending orthogonally from the dielectric substrate and electrically connected to the first gate driver 38a and the second gate driver 38b using bonding wires. It should be understood that, in some embodiments, the first gate driver 38a and the second gate driver 38b may be located on a separate circuit board from the first power module 32a and connected to the first power module 32a via wires, contacts, or other conductors.

In an exemplary embodiment, the first gate driver 38a is configured to control the first power switch die 36a with the first switching slew rate as determined at block 112. The second gate driver 38b is configured to control the second power switch die 36b with the second switching slew rate as determined at block 112. If block 112 was bypassed after block 108, default switching slew rates are configured. In a non-limiting example, to configure the first gate driver 38a and the second gate driver 38b, the first switching slew rate and the second switching slew rate are saved to a non-transitory memory of the first gate driver 38a and the second gate driver 38b using a programming device. In another non-limiting example, the first switching slew rate and the second switching slew rate are saved to the media 24 of the controller 14 for later retrieval and transmission to the first gate driver 38a and the second gate driver 38b. After block 110, the method 100 proceeds to block 114.

At block 114, a total power loss of the first power module 32a is determined. In an exemplary embodiment, the total power loss is a sum of the total switching loss and the total conduction loss of the first power switch die 36a and the second power switch die 36b. Therefore, the total power loss is determined based at least in part on the electrical characteristics of the first power switch die 36a and the second power switch die 36b determined at block 104. After block 114, the method 100 proceeds to block 116.

At block 116, an optimal affixment location is determined for the first power module 32a based at least in part on the total power loss of the first power module 32a determined at block 114. In the scope of the present disclosure, the optimal affixment location is a location on the heatsink 30 which will provide optimal cooling performance for the first power module 32a. In a non-limiting example, the optimal affixment location is defined relative to the coolant inlet 34a and the coolant outlet 34b of the heatsink 30. As discussed above, the temperature of the coolant entering at the coolant inlet 34a is lower than the temperature of the coolant exiting at the coolant outlet 34b, and a corresponding temperature gradient exists within the heatsink 30 between the coolant inlet 34a and the coolant outlet 34b. In an exemplary embodiment, a distance between the coolant inlet 34a and the optimal affixment location is negatively correlated with the total power loss of the first power module 32a. In other words, if the first power module 32a has a high total power loss, the optimal affixment location is near the coolant inlet 34a such that the first power module 32a is exposed to colder coolant, reducing the operating temperature of the first power module 32a. By reducing the operating temperature of the first power module 32a, the total power loss of the first power module 32a is also reduced. Therefore, power switch dies having a total power loss greater than the predetermined die total power loss threshold may be utilized to build the first power module 32a. After block 116, the method 100 proceeds to block 118.

At block 118, the first power module 32a is affixed to the heatsink 30 at the optimal affixment location determined at block 116. It should be understood that the method 100 may also include additional steps including, for example, electrical connection of components, testing of components, enclosure, encapsulation, or conformal coating of components, quality assurance, and/or the like. After block 118, the method 100 proceeds to enter a standby state at block 120.

In an exemplary embodiment, the method 100 is repeatedly restarted at block 102 to produce the plurality of power modules 32 (e.g., the second power module 32b and the third power module 32c) and affix each of the plurality of power modules 32 to the heatsink 30 to complete the power inverter 20.

The method 100 of the present disclosure offers several advantages. By manufacturing the power inverter 20 according to the method 100, power switch dies may be utilized even if they have electrical characteristics outside of normal acceptable ranges, increasing manufacturing efficiency and reducing material use while maintaining appropriate thermal performance of the power inverter 20.

The description of the present disclosure is merely exemplary in nature and variations that do not depart from the gist of the present disclosure are intended to be within the scope of the present disclosure. Such variations are not to be regarded as a departure from the spirit and scope of the present disclosure.

What is claimed is:

1. A method for manufacturing a power inverter, the method comprising:
determining a plurality of electrical characteristics of each of a first power switch die and a second power switch die, wherein the plurality of electrical characteristics includes at least: a conduction loss and a switching loss; and
manufacturing the power inverter using at least the first power switch die and the second power switch die based at least in part on the plurality of electrical characteristics of each of the first power switch die and the second power switch die.

2. The method of claim 1, wherein determining the plurality of electrical characteristics further comprises:
testing each of the first power switch die and the second power switch die to determine the plurality of electrical characteristics of each of the first power switch die and the second power switch die.

3. The method of claim 1, wherein manufacturing the power inverter further comprises:
assembling at least one power module, wherein the at least one power module includes at least: the first power switch die and the second power switch die; and
manufacturing the power inverter including the at least one power module.

4. The method of claim 3, wherein assembling the at least one power module further comprises:
assembling the at least one power module, wherein a switching loss of the first power switch die is greater than or equal to a predetermined die switching loss threshold, and wherein a total switching loss of the first power switch die and the second power switch die is less than or equal to a predetermined total switching loss threshold.

5. The method of claim 4, wherein assembling at least one power module further comprises:
assembling the at least one power module, wherein the at least one power module further includes a first gate driver for controlling the first power switch die and a second gate driver for controlling the second power switch die;
configuring the first gate driver to control the first power switch die with a first switching slew rate; and
configuring the second gate driver to control the second power switch die with a second switching slew rate, wherein the second switching slew rate is less than the first switching slew rate.

6. The method of claim 5, wherein configuring the first gate driver and configuring the second gate driver further comprises:
determining the first switching slew rate and the second switching slew rate such that the total switching loss of the first power switch die and the second power switch die is less than or equal to a predetermined total switching loss threshold and such that a first voltage overshoot of the first power switch die and a second voltage overshoot of the second power switch die are less than or equal to a predetermined voltage overshoot threshold.

7. The method of claim 3, wherein assembling at least one power module further comprises:
assembling the at least one power module, wherein a conduction loss of the first power switch die is greater than or equal to a predetermined die conduction loss threshold, wherein a conduction loss of the second power switch die is less than or equal to the predetermined die conduction loss threshold, and wherein a total conduction loss of the first power switch die and the second power switch die is less than or equal to a predetermined total conduction loss threshold.

8. The method of claim 3, wherein assembling the at least one power module further comprises:
comparing the conduction loss of the first power switch die to a predetermined die conduction loss threshold;
comparing the conduction loss of the second power switch die to the predetermined die conduction loss threshold;
procuring one or more additional power switch dies having a conduction loss less than or equal to the predetermined die conduction loss threshold in response to determining that the conduction loss of the first power switch die and the conduction loss of the second power switch die is greater than the predetermined die conduction loss threshold, wherein the one or more additional power switch dies are procured from one of a plurality of suppliers based at least in part on a stock status of each of the plurality of suppliers; and
assembling the at least one power module using one or more of the additional power switch dies.

9. The method of claim 3, wherein manufacturing the power inverter further comprises:
determining a total power loss of the at least one power module based at least in part on the electrical characteristics of the first power switch die and the electrical characteristics of the second power switch die; and
affixing the at least one power module to a heatsink based at least in part on the total power loss of the at least one power module.

10. The method of claim 9, wherein affixing the at least one power module to the heatsink further comprises:
determining an optimal affixment location of the at least one power module on the heatsink relative to a coolant inlet of the heatsink and a coolant outlet of the heatsink, wherein a distance between the coolant inlet and the optimal affixment location is negatively correlated with the total power loss of the at least one power module.

11. A power inverter for a vehicle comprising:
a heatsink including a coolant inlet and a coolant outlet; and
a power module affixed to the heatsink including at least a first power switch die and a second power switch die selected based at least in part on a plurality of electrical characteristics of each of the first power switch die and the second power switch die.

12. The power inverter of claim 11, wherein the plurality of electrical characteristics includes at least a power loss, wherein the power loss is a sum of a switching loss and a conduction loss, and wherein a total power loss of the first power switch die of the power module and the second power switch die of the power module is less than or equal to a predetermined total power loss threshold.

13. The power inverter of claim 12, wherein the power module further comprises:
a first gate driver for controlling the first power switch die, wherein the first gate driver is configured to control the first power switch die with a first switching slew rate; and
a second gate driver for controlling the second power switch die, wherein the second gate driver is configured to control the second power switch die with a second switching slew rate, and wherein the second switching slew rate is less than the first switching slew rate.

14. The power inverter of claim 13, wherein the first switching slew rate and the second switching slew rate are determined such that the total power loss of the first power switch die and the second power switch die is less than or equal to a predetermined total power loss threshold and such that a first voltage overshoot of the first power switch die and a second voltage overshoot of the second power switch die are less than or equal to a predetermined voltage overshoot threshold.

15. The power inverter of claim 13, wherein the first switching slew rate and the second switching slew rate are determined such that the first voltage overshoot of the first power switch die and the second voltage overshoot of the second power switch die are less than or equal to the predetermined voltage overshoot threshold in response to determining that the total power loss of the first power switch die and the second power switch die is less than or equal to the predetermined total power loss threshold.

16. The power inverter of claim 11, wherein the power module is affixed to the heatsink at an optimal affixment location relative to the coolant inlet based at least in part on a total power loss of the power module.

17. The power inverter of claim 16, wherein a distance between the coolant inlet and the optimal affixment location is negatively correlated with the total power loss of the power module.

18. A method for manufacturing a power inverter for a vehicle, the method comprising:
testing each of a first power switch die and a second power switch die to determine a plurality of electrical characteristics of each of the first power switch die and the second power switch die, wherein the plurality of electrical characteristics includes at least: a conduction loss and a switching loss; and
assembling at least one power module based at least in part on the plurality of electrical characteristics of each of the first power switch die and the second power switch die, wherein the at least one power module includes at least: the first power switch die and the second power switch die; and
manufacturing the power inverter including the at least one power module based at least in part on the plurality of electrical characteristics of each of the first power switch die and the second power switch die.

19. The method of claim 18, wherein assembling at least one power module further comprises:
assembling the at least one power module, wherein a switching loss of the first power switch die is greater than or equal to a predetermined die switching loss threshold, and wherein the at least one power module further includes a first gate driver for controlling the first power switch die and a second gate driver for controlling the second power switch die;
determining a first switching slew rate and a second switching slew rate such that a total switching loss of the first power switch die and the second power switch die is less than or equal to a predetermined total switching loss threshold and such that a first voltage overshoot of the first power switch die and a second voltage overshoot of the second power switch die are less than or equal to a predetermined voltage overshoot threshold;
configuring the first gate driver to control the first power switch die with the first switching slew rate; and
configuring the second gate driver to control the second power switch die with the second switching slew rate, wherein the second switching slew rate is less than the first switching slew rate.

20. The method of claim 19, wherein manufacturing the power inverter further comprises:
determining a total power loss of the at least one power module based at least in part on the electrical characteristics of the first power switch die and the electrical characteristics of the second power switch die;
determining an optimal affixment location of the at least one power module on a heatsink relative to a coolant inlet of the heatsink and a coolant outlet of the heatsink, wherein a distance between the coolant inlet and the optimal affixment location is negatively correlated with the total power loss of the at least one power module; and
affixing the at least one power module to a heatsink based at least in part on the optimal affixment location.
